(19) United States
(12) Patent Application Publication
(10) Pub. No.: US 2010/0156479 A1
(43) Pub. Date: Jun. 24, 2010

(54) POWER-ON RESET CIRCUIT AND ADJUSTING METHOD THEREFOR

(75) Inventors: Yasushi Matsubara, Tokyo (JP); Satoshi Morishita, Tokyo (JP)

Correspondence Address: MORRISON & FOERSTER LLP, 1650 TYSONS BOULEVARD, SUITE 400, MCLEAN, VA, 22102, US

(73) Assignee: Elpida Memory, Inc., Tokyo (JP)

(21) Appl. No.: 12/644,420

(22) Filed: Dec. 22, 2009

(30) Foreign Application Priority Data
Dec. 22, 2008 (JP) 2008-325281

(51) Int. Cl. H03L 7/00

(52) U.S. Cl. 327/143

(57) ABSTRACT

A power-on reset circuit includes a detection-voltage producing circuit that produces a detection voltage proportional to a power-supply voltage, and a power-on determining circuit that activates a power-on reset signal when a detection voltage is less than the power-on determining voltage and inactivates the power-on reset signal when the detection voltage is equal to or greater than the power-on determining voltage. In the detection-voltage producing circuit, a fuse element used for adjusting a proportional constant between a power-supply voltage and the detection voltage is arranged. Thereby, the power-on determining voltage becomes adjustable. Accordingly, the power-on determining voltage can be made closer to a design value when there is a deviation from the design value in the power-on determining voltage after the semiconductor device is manufactured.

### BACKGROUND OF THE INVENTION

1. Field of the Invention The present invention relates to a power-on reset circuit built in a semiconductor device, and an adjusting method therefore.

2. Description of Related Art

Many semiconductor devices include a power-on reset circuit that resets an internal circuit in response to power activation (see Japanese Patent Application Laid-open No. H5-119871). The power-on reset circuit senses an increase in the power-supply voltage up to a predetermined power-on determining voltage and generates a power-on reset signal, based on a fact that it takes a certain amount of time to stabilize a power-supply voltage after the power activation.

A circuit disclosed by Japanese Patent Application Laid-open No. H7-141041 is a known circuit capable of adjusting a reference voltage within a semiconductor device although it is not a power-on reset circuit.

However, researches by the present inventors have revealed that the power-on determining voltages in the power-on reset circuit vary with chips due to manufacturing conditions and the like. When the power-on determining voltage deviates from a design value because of this variation, timing of change in the power-on reset signal deviates from a design value.

FIG. 9 is a waveform diagram for explaining this, where a voltage V2 is a design power-on determining voltage. In a chip 2 that has the design power-on determining voltage V2 at precise, level of power-on reset signal PON rises in accordance with rise of a power-supply voltage VPERI after the power activation, and then is inactivated to a low level when the power-supply voltage VPERI reaches V2. In contrast, in a chip 1, the power-on determining voltage V1 is lower than the design value (V1<V2), and accordingly, the power-on reset signal PON is inactivated to a low level before the power-supply voltage VPERI reaches V2. Conversely, in a chip 3, a power-on determining voltage V3 is higher than the design value (V2<V3), and accordingly, the power-on reset signal PON is not inactivated to a low level until after the power-supply voltage VPERI reaches V3, even after the power-supply voltage VPERI reaches V2.

Upon practical power activation, not so serious problem arises even when the timing of inactivation of the power-on reset signal PON deviates from the design value in some degree. However, it is found that the deviation in the power-on determining voltage brings a problem during a normal operation after the power activation.

That is, as shown in FIG. 10, when the power-supply voltage VPERI is superimposed with noise during a practical operation and falls below the power-on determining voltage, the power-on reset signal PON is output in error. That is, VPERI-V2 is a design noise margin. However, when the power-on determining voltage is V3, which is higher than the design value V2, as shown in FIG. 10, the noise margin decreases to VPERI-V3, which causes the power-on reset signal PON to be easily output in error.

On the other hand, when the power-on determining voltage is too low, there is a risk that the internal circuit cannot be reset properly at the power activation. Thus, the variation in the power-on determining voltage produces various problems.

### SUMMARY OF THE INVENTION

The present invention seeks to solve one or more of the above problems, or to improve upon those problems at least in part.

In one embodiment, there is provided a device comprising: an internal circuit that receives a power-supply voltage; a power-on determining circuit that supplies a power-on reset signal to the internal circuit in response to the power supply voltage and activates the power-on reset signal, when a level of the power-supply voltage is lower than a level of a power-on determining voltage, so that the internal circuit performs a predetermined reset operation, and deactivates the power-on reset signal when the level of the power-supply voltage is higher than the level of the power-on determining voltage; and a detection-voltage producing circuit that adjusts the level of the power-on determining voltage.

In another embodiment, there is provided a device comprising: first and second power supply lines; an internal circuit coupled between the first and second power supply lines; a detection-voltage producing circuit that is connected between the first and second power supply lines to produce a detection voltage, a level of the detection voltage being substantially proportional to a level of a power-supply voltage applied between the first and second power supply lines, the detection-voltage producing circuit that is capable of adjusting a proportional constant between the level of the power-supply voltage and the level of the detection voltage; and a power-on determining circuit that supplies a power-on reset signal to the internal circuit in response to the power supply voltage, activates the power-on reset signal, when the level of the detection voltage is lower than a level of a predetermined power-on determining voltage, so that the internal circuit performs a predetermined reset operation, and deactivates the power-on reset signal when the level of the detection voltage is higher than the level of the predetermined power-on determining voltage.

In another embodiment, there is provided a method of adjusting a level of a power-on determining voltage of a device, the device compressing an internal circuit, a power-on determining circuit and a detection-voltage producing circuit, the power-on determining circuit activating a power-on reset signal, when a level of a power-supply voltage is lower than a level of a power-on determining voltage, so that the internal circuit performs a predetermined reset operation, and deactivating the power-on reset signal when the level of the power-supply voltage is higher than the level of the power-on determining voltage, the method comprising: detecting the level of the power-on determining voltage; comparing the level of the power-on determining voltage with a level of a design power-on determining voltage; and performing a fuse trimming, in which one or ones of a plurality of fuse element included in the detection-voltage producing circuit are trimmed so that the level of the power-on determining voltage is adjusted, based on a result of the comparing.

In another embodiment, there is provided a power-on reset-voltage managing system that is applied to a semiconductor device. The system includes a power-on reset circuit in which a power-on reset signal is activated when a power-supply voltage is less than a power-on determining voltage, and the power-on reset signal is inactivated when the power-supply voltage is equal to or greater than the power-on determining voltage, comprising: a voltage detecting unit that detects the power-on determining voltage by monitoring the power-on reset signal in a wafer state; and a storage unit that stores therein the detected power-on determining voltage or information related thereto in association with a position of the semiconductor device on a wafer.

According to the present invention, the power-on determining voltage can be adjusted. Therefore, when there is a deviation from the design value in the power-on determining voltage after the semiconductor device is manufactured, the power-on determining voltage can be made closer to the design value. This enables to prevent the various problems resulting from the variation in the power-on determining voltage.

When the power-on determining voltage prior to the adjustment or the information related thereto is stored in association with the position of the semiconductor device on the wafer, it is also possible to understand processing conditions, enabling proper feedback to subsequent lots.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a block diagram showing a configuration of a semiconductor device which includes a power-on reset circuit according to one embodiment of the present invention;

FIG. 2 is a circuit diagram of the power-on reset circuit;

FIG. 3 is a waveform diagram for explaining an operation of the power-on reset circuit;

FIG. 4 is a flowchart for explaining a method for adjusting the power-on reset circuit;

FIG. 5 is a circuit diagram of a power-on reset circuit according to a modification of the present embodiment;

FIG. 6 is a block diagram showing an example in which the internal circuit is reset by a plurality of power-on reset circuits;

FIG. 7 is a circuit diagram of the power-on reset circuit according to another modification of the present embodiment;

FIG. 8 is a schematic diagram showing a configuration of a power-on reset-voltage managing system;

FIG. 9 is a waveform diagram for explaining the deviation of power-on determining voltage; and

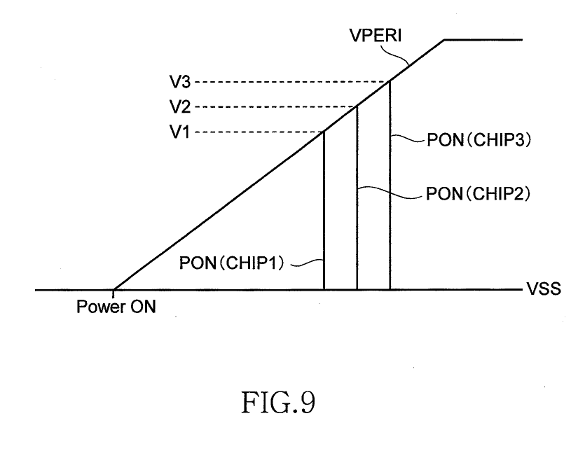

FIG. 10 is a waveform diagram, where the power-supply voltage is superimposed with noise during a practical operation and falls below the power-on determining voltage.

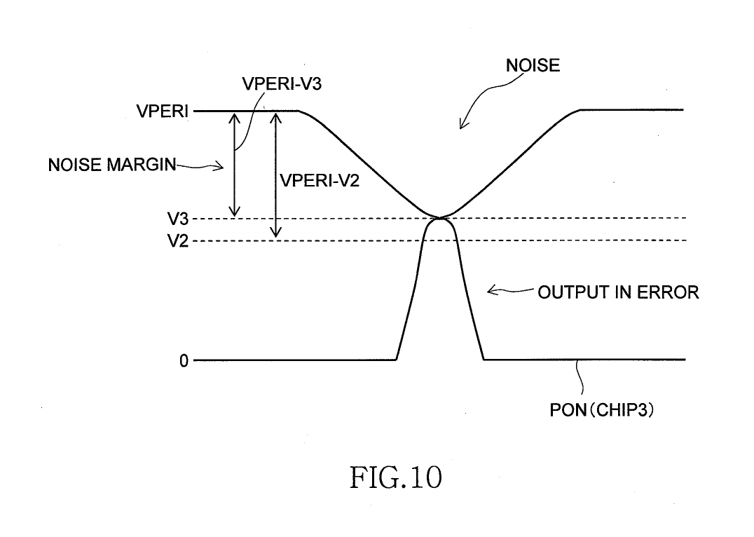

### DETAILED DESCRIPTION OF THE EMBODIMENTS

Preferred embodiments of the present invention will be explained below in detail with reference to the accompanying drawings.

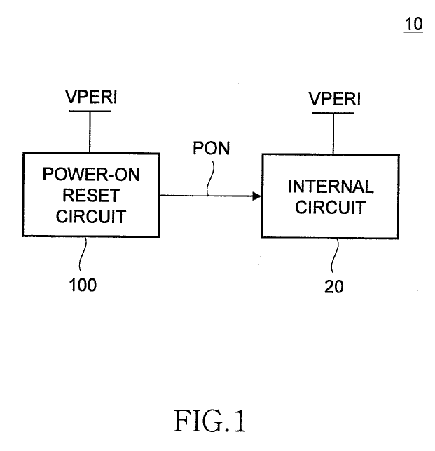

FIG. 1 is a block diagram showing a configuration of a semiconductor device 10 which includes a power-on reset circuit 100 according to one embodiment of the present invention.

The semiconductor device 10 shown in FIG. 1 includes the power-on reset circuit 100 and an internal circuit 20. The internal circuit 20 is a circuit block that provides main functions of the semiconductor device 10, and includes a memory cell array and its peripheral circuit (address decoder and the like) when the semiconductor device 10 is a DRAM (Dynamic Random Access Memory), for example. While a variety of operating voltages is supplied to the internal circuit 20, only a power-supply voltage VPERI among these voltages is shown in FIG. 1. The power-supply voltage VPERI is, for example, an operating voltage for the peripheral circuit of the DRAM, and is produced by stepping down a power-supply voltage VDD that is supplied to a power supply terminal.

The power-supply voltage VPERI is supplied also to the power-on reset circuit 100. The power-on reset circuit 100 detects power activation, and senses reach of the power-supply voltage VPERI to a power-on determining voltage after the power activation, to cause generation of a power-on reset signal PON. The power-on reset signal PON is supplied to the internal circuit 20. The internal circuit 20 performs a predetermined reset operation when it receives the power-on reset signal PON.

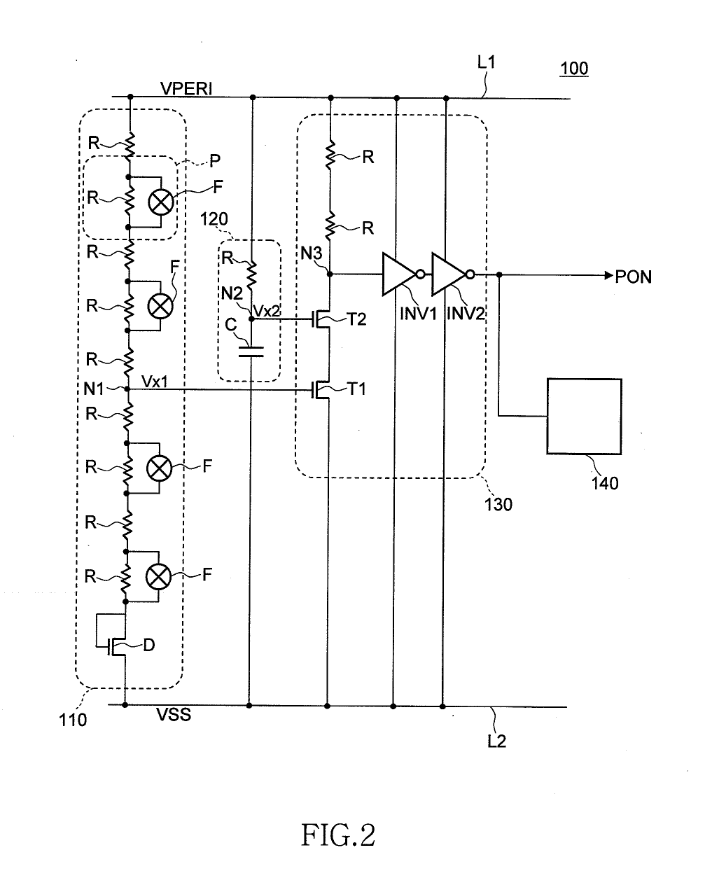

FIG. 2 is a circuit diagram of the power-on reset circuit 100.

As shown in FIG. 2, the power-on reset circuit 100 includes a detection-voltage producing circuit 110, a time constant circuit 120, a power-on determining circuit 130, and a monitor pad 140.

The detection-voltage producing circuit 110 includes a plurality of linear resistive elements R and a diode element D connected in series between a power supply line L1 that is supplied with the power-supply voltage VPERI and a power supply line L2 that is supplied with a power-supply voltage VSS, and fuse elements F that are connected in parallel with some of the resistive elements R. A detection voltage Vx1 is output from a predetermined node N1. That is, the detection voltage Vx1 that is output through the node N1 is obtained by dividing the voltages applied between the power supply lines L1 and L2 (VPERI=VPERI−VSS) by the linear resistances, that is, a voltage proportional to the power-supply voltage VPERI. The diode element D is an element in which an N-channel MOS transistor is diode-connected, and functions as a current source.

Resistance values of the fuse elements F are set to be sufficiently lower than resistance values of the linear resistive elements R. Accordingly, when the fuse element F is connected, a resistance value of a parallel circuit P including the linear resistive element R and the fuse element F is low, and conversely, when the fuse element F is disconnected, the resistance value of the parallel circuit P including the linear resistive element R and the fuse element F is high. This makes it possible to adjust a proportional constant between the power-supply voltage VPERI and the detection voltage Vx1 by trimming the fuse element F.

The time constant circuit 120 includes a linear resistive element R and a capacitive element C connected in series between the power supply lines L1 and L2, from which a detection voltage Vx2 is output through a node N2 which is a connection point therebetween. The time constant circuit 120 is a type of protecting circuit, delaying inactivation of the power-on reset signal PON for at least a certain time even when the power-supply voltage VPERI rises abruptly after the power activation. Accordingly, when the rise in the power-supply voltage VPERI is somewhat gradual, like at normal power activation, the operation of the time constant circuit 120 does not affect the timing of the inactivation of the power-on reset signal PON.

The power-on determining circuit 130 includes resistive elements R, transistors T1 and T2, connected in series between the power supply lines L1 and L2 and an output circuit OUT. The detection voltage Vx1 produced by the detection-voltage producing circuit 110 is supplied to a gate of the transistor T1, and the detection voltage Vx2 produced by the time constant circuit 120 is supplied to a gate of the transistor T2. A node N3 that is a connection point between a drain of the transistor T2 and the linear resistive element R is connected to an input terminal of two-stage inverters INV1 and INV2 that configure the output circuit OUT. An output of the output circuit OUT is the power-on reset signal PON. The positions of the transistors T1 and T2 can be reversed. When the positions of the transistors T1 and T2 are reversed, the node N3 is a connection point between a drain of the transistor T1 and the resistive element R.

The monitor pad 140, which is connected to an output terminal of the output circuit OUT, enables contact by a probe during testing performed in a wafer state. This makes it possible to monitor directly the power-on reset signal PON using an external tester, or the like.

The circuit configuration of the power-on reset circuit 100 is described above. An operation of the power-on reset circuit 100 is explained next.

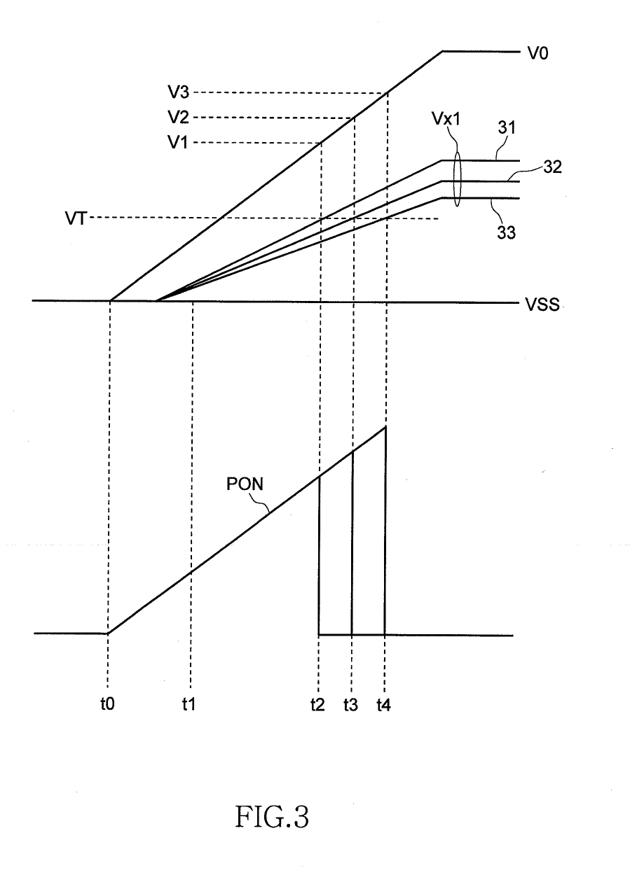

FIG. 3 is a waveform diagram for explaining an operation of the power-on reset circuit 100.

As shown in FIG. 3, prior to a time t0, power is not supplied to the semiconductor device 10, and thus the value of the power-supply voltage VPERI is zero (=VSS). When the power is supplied at the time t0, the power-supply voltage VPERI begins to rise towards a target value V0. However, it does not immediately reach the target value V0 but rises somewhat gradually.

In a state immediately after the power-supply voltage VPERI begins to rise, at least one of the transistors T1 and T2 is in an OFF state, and thus a level at the node N3 matches the level of the power-supply voltage VPERI. In an initial state, a potential at an input node of the inverter INV2 is set to the VSS level. Because of this, an output node of the inverter INV2 immediately after the power-supply voltage VPERI begins to rise is conductive with the power supply line L1 via a PMOS transistor (not shown) within the inverter INV2. As a result, a potential at the output node of the inverter INV2, that is, the level of the power-on reset signal PON matches the level of the power-supply voltage VPERI. That is, the power-on reset signal PON is in an active state, and rises following the power-supply voltage VPERI.

Subsequently, at a time t1, a level at the node N2 included in the time constant circuit 120 exceeds a threshold value of the transistor T2. This causes the transistor T2 to turn ON, and because the transistor T1 is still OFF, the level at the node N3 is kept at the power-supply voltage VPERI. At this time, a period between the time t0 and the time t1 is set to be equal to or greater than a minimum period required until the internal circuit 20 shown in FIG. 1 can operate after the power activation. As a result, even when the power-supply voltage VPERI rises abruptly, the power-on reset signal PON does not become inactive until a certain period has elapsed.

During this period, the detection voltage Vx1 output from the node N1 of the detection-voltage producing circuit 110 rises in proportion to the power-supply voltage VPERI as shown by a property 32. When the level of the power-supply voltage VPERI reaches the power-on determining voltage V2 at a time t3, the detection voltage Vx1 exceeds a threshold value VT of the transistor T1. As a result, the transistor T1 is turned ON, the node N3 and the power supply line L2 is connected electrically, charges at the node N3 is emitted into the power supply line L2, and a potential at the node N3 falls. When a resistance between the node N3 and the power supply line L1 (resistance value of a combined resistance of two linear resistances R in FIG. 2) has a sufficiently larger magnitude than a resistance between the node N3 and the power supply line L2 (combined resistance of an ON resistances of the transistors T1 and T2 in FIG. 2), the potential at the node N3 falls to near the power-supply voltage VSS. Preferably, the resistance between the node N3 and the power supply line L1 has a magnitude that defines the potential of the node N3 so as to be at least equal to or less than a potential of an input signal into the inverter INV1 that causes a logical level of an output signal from the inverter INV1 to be “1” when both of the transistors T1 and T2 are in the conductive states. More preferably, when both of the transistors T1 and T2 are in the conductive states, the magnitude of the resistance between the node N3 and the power supply line L1 is at least 10 times larger than that of the resistance between the node N3 and the power supply line L2 (that is, the combined resistance of the ON resistances of the transistors T1 and T2). When the potential of the node N3 falls to near the power-supply voltage VSS, the potential of the INV1 output node follows the power-supply voltage VPERI. As a result, the PMOS transistor (not shown) within the inverter INV2 becomes nonconductive, and an NMOS transistor (not shown) within the inverter INV2 becomes conductive, thereby changing the level of the power-on reset signal PON to the power-supply voltage VSS. That is, the power-on reset signal PON transits to an inactive state.

The power-on determining voltage V2 is the design value. In other words, it is the value of the power-supply voltage VPERI at which the level of the detection voltage Vx1 output from the node N1 should match the threshold value VT of the transistor T1. However, the proportional constant between the power-supply voltage VPERI and the detection voltage V×1 varies depending on variation in the resistance values of the linear resistive elements R that configure the detection-voltage producing circuit 110, and thus the detection voltage Vx1 obtained when the power-supply voltage VPERI reaches the power-on determining voltage V2 does not always match the threshold value VT of the transistor T1.

Specifically, when the proportional constant between the power-supply voltage VPERI and the detection voltage V×1 is greater than a design value, the rise of the detection voltage Vx1 accompanying the rise in the power-supply voltage VPERI is faster than in the property 32, as shown by a property 31 in FIG. 3. As a result, the level of the detection voltage Vx1 exceeds the threshold value VT of the transistor T1 when the power-supply voltage VPERI reaches a voltage V1 (<V2) at a time t2, prior to reaching the voltage V2, which is the design value. In this case, the power-on reset signal PON will be inactivated earlier than that in the design.

In contrast, when the proportional constant between the power-supply voltage VPERI and the detection voltage Vx1 is less than the design value, the rise of the detection voltage Vx1 accompanying the rise of the power-supply voltage VPERI is delayed behind the property 32, as shown by a property 33 in FIG. 3. As a result, the level of the detection voltage Vx1 does not exceed the threshold value of the transistor T1 until reaching a voltage V3 at a time t4, even after the power-supply voltage VPERI reaches the voltage V2, which is the design value. In this case, the power-on reset signal PON becomes inactivated later than that in the design.

It has already been explained above that the variation causes the various problems and, in particular, serious problems are caused when noise is superposed on the power-supply voltage VPERI. In this embodiment, it is possible to correct the variation afterward. A method therefor will be explained below.

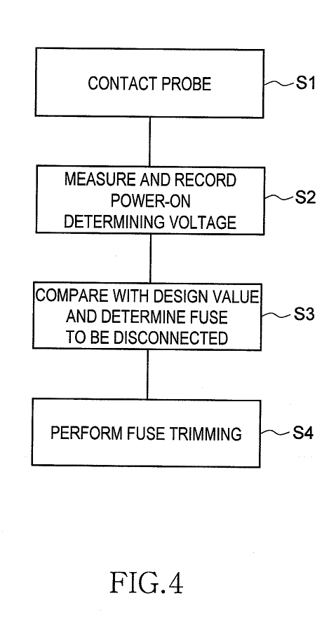

FIG. 4 is a flowchart for explaining a method for adjusting the power-on reset circuit 100. All of the processes shown in FIG. 4 are preferably performed in a wafer state although the present invention is not limited thereto.

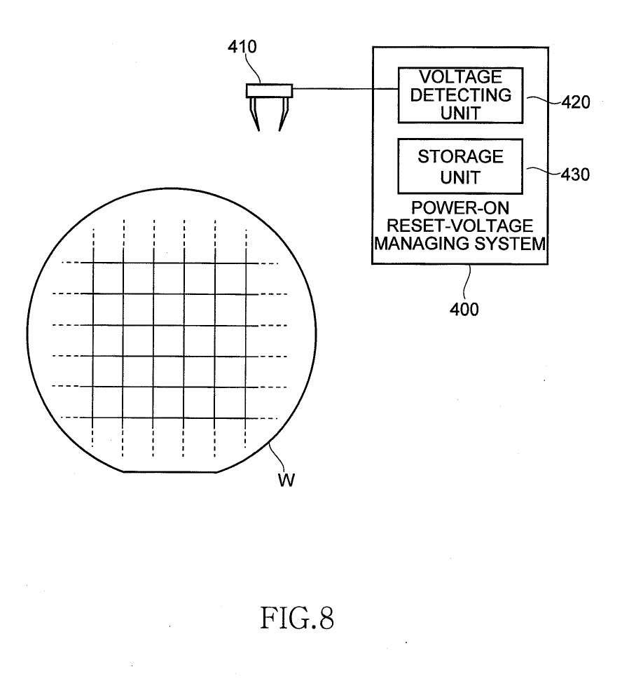

First, a probe of an external tester is brought into contact with the monitor pad 140 of each chip formed on a wafer (step S1). The external tester probe is also brought into contact with a power supply terminal (not shown), and a power-supply voltage supplied to the power supply terminal in this state is increased in a stepwise manner. A power-supply voltage at which the power-on reset signal PON transits from an active state to an inactive state is recorded for each chip (step S2). The power-supply voltages supplied to the power supply terminal is preferably varied with a pitch of 0.05 V, for example, in a predetermined voltage range near the design value of the power-on determining voltage (for example, 0.8 V to 1.4 V). In this way, the power-on determining voltage is detected and recorded for the power-on reset circuit 100 provided in each of the chips. The processes can be performed using a probe 410 and a voltage detecting unit 420 shown in FIG. 8.

The stored power-on determining voltage is then compared to the design value to determine a degree to which the stored power-on determining voltage deviates from the design value, thereby determining a fuse element F to be disconnected (step S3). Specifically, when the power-on determining voltage is lower than the design value, the proportional constant between the power-supply voltage VPERI and the detection voltage Vx1 needs to be smaller, and thus, among the fuse elements F included in the detection-voltage producing circuit 110, the fuse element F on the side of the power supply line L1 when viewed from the node N1 is disconnected. Conversely, when the power-on determining voltage is greater than the design value, the proportional constant between the power-supply voltage VPERI and the detection voltage Vx1 needs to be larger, and thus, among the fuse elements F included in the detection-voltage producing circuit 110, the fuse element F on the side of the power supply line L2 when viewed from the node N1 is disconnected. An amount of the adjustment can be selected through the number of fuse elements F to be disconnected, or through the resistance values of the linear resistive elements R that are connected in parallel with the fuse elements F.

Fuse trimming is then performed by applying a laser beam to the fuse element F to be disconnected (step S4). Thereby, the power-on determining voltage is practically changed, which makes it possible to obtain a power-on determining voltage near the design value. The processes from steps S1 to S4 can be performed iteratively, making it possible to obtain the power-on determining voltage much closer to the design value.

As described above, according to the present embodiment, a power-on determining voltage that is nearer the design value can be obtained, because the power-on determining voltage is acquired by monitoring the power-on reset signal PON directly and the power-on determining voltage is adjusted by performing fuse trimming based thereon. This makes it possible to prevent the various problems brought about by the variation in the power-on determining voltage, and in particular, to prevent unintended activation of the power-on reset signal PON caused when noise is superposed on the power-supply voltage VPERI.

Modifications of the embodiment are explained below.

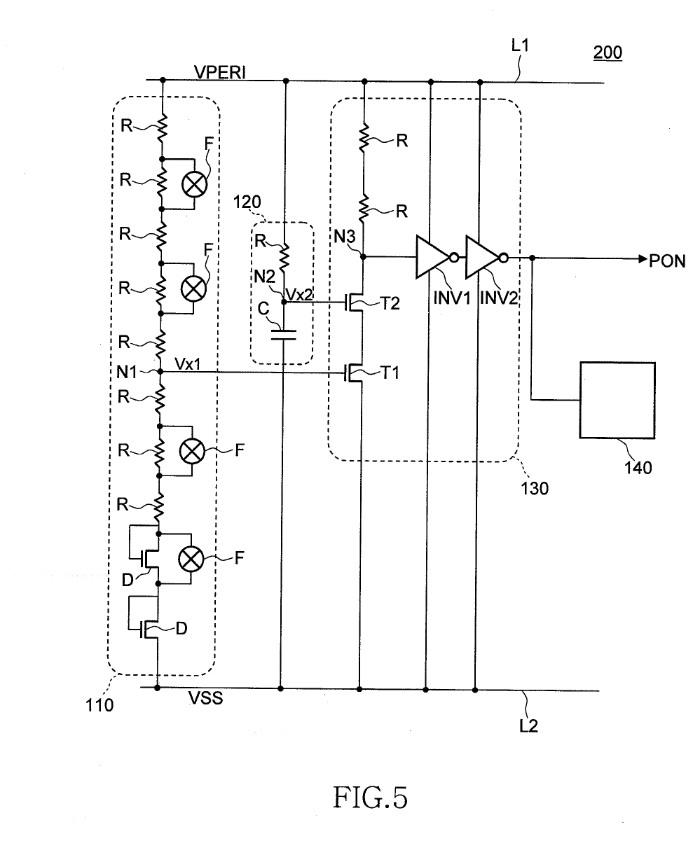

FIG. 5 is a circuit diagram of a power-on reset circuit 200 according to a modification of the present embodiment.

The power-on reset circuit 200 shown in FIG. 5 differs from the power-on reset circuit 100 shown in FIG. 2 in that the fuse elements F are connected in parallel with diodes D. The other points are identical to the power-on reset circuit 100 shown in FIG. 2, and thus the like parts are designated by like reference numerals and redundant explanations thereof will be omitted. The power-on determining voltage can be adjusted by arranging the fuse elements F in parallel with the diode elements D that are current sources, rather than the resistive elements R, in this way and then performing trimming.

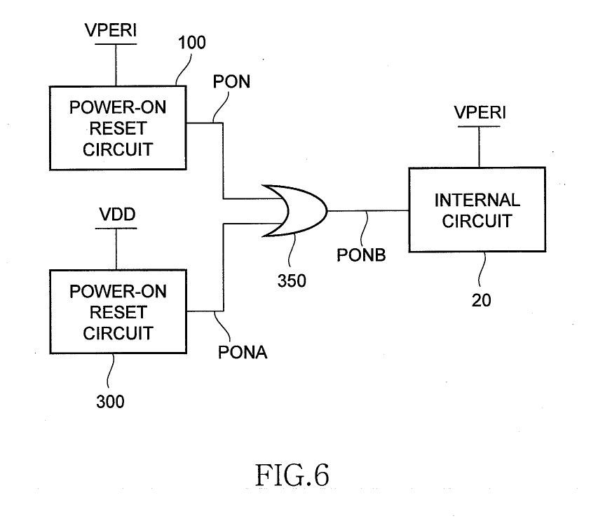

FIG. 6 is a block diagram showing an example in which the internal circuit 20 is reset by a plurality of power-on reset circuits.

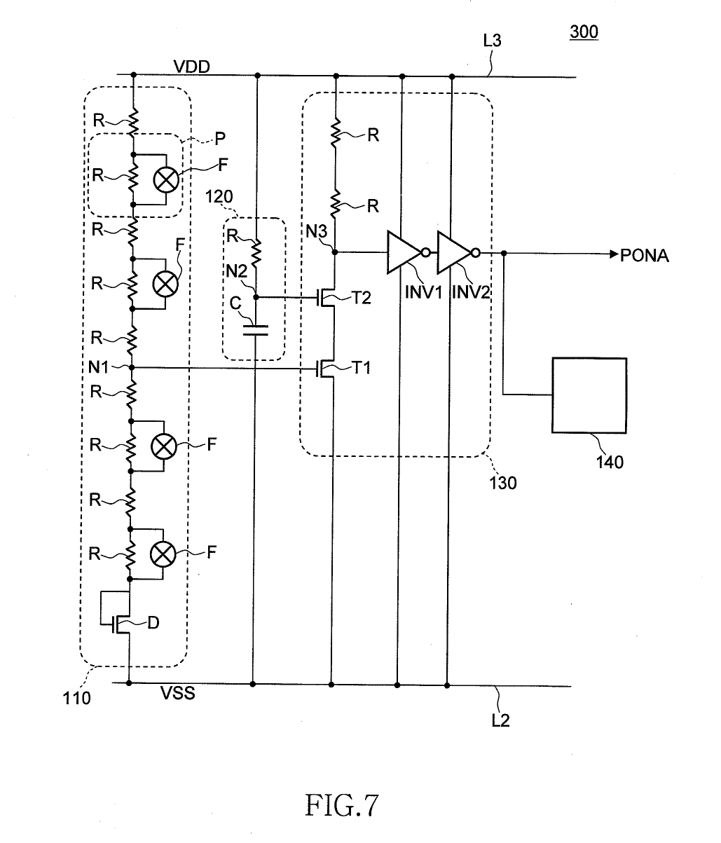

In an example shown in FIG. 6, two power-on reset circuits 100 and 300 are arranged, and an output PONB that is obtained by combining power-on reset signals PON and PONA, output from the power-on reset circuits 100 and 300, by an OR circuit 350 is supplied to the internal circuit 20. The power-on reset circuit 100 is shown in FIG. 2, and the other power-on reset circuit 300 is shown in FIG. 7.

As shown in FIG. 7, the power-on reset circuit 300 uses a power supply line L3 instead of the power supply line L1, and has the same circuit configuration as that of the power-on reset circuit 100 shown in FIG. 2, with the exception of a power-supply voltage VDD being supplied to the power supply line L3. That is, in contrast to the power-on reset circuit 100 shown in FIG. 2 that monitors the power-supply voltage VPERI, the power-on reset circuit 300 shown in FIG. 7 monitors the power-supply voltage VDD. Accordingly, the internal circuit 20 is reset only when both of the outputs PON and PONA from the two power-on reset circuits 100 and 300 are inactivated to low levels.

This is because different power-supply voltages are used in the semiconductor device, and rates of rises in these power-supply voltages are not always the same. That is, when a power-on reset circuit is provided for only a power-supply voltage that rises quickly, reset for a circuit block that uses a power-supply voltage that rises slowly is performed before a sufficient power-supply voltage is supplied, which is prevented by the use of the plural power-on reset circuits. In order to securely prevent this, the power-on reset circuits need to be arranged for all types of power-supply voltages used in the semiconductor device; however, because the power-on reset circuit occupies a relatively large area on the chip, it is not advisable to arrange the power-on reset circuits for all the types of power-supply voltages.

In consideration of this point, in the modification shown in FIG. 6, the power-on reset circuits are assigned for the two power-supply voltages: the power-supply voltage VDD supplied from the outside and the power-supply voltage VPERI produced internally. When the outputs PON and PONA of these two power-on reset circuits 100 and 300 are both inactivated to the low levels, the internal circuit 20 is reset by the power-on reset signal PONB. This enables the internal circuit 20 to be reset in consideration of both the rate of the rise in the power-supply voltage supplied from the outside and the rate of the rise in the power-supply voltage produced internally.

FIG. 8 is a schematic diagram showing a configuration of a power-on reset-voltage managing system 400.

The power-on reset-voltage managing system 400 shown in FIG. 8 includes the probe 410, the voltage detecting unit 420, and a storage unit 430. The functions of the probe 410 and the voltage detecting unit 420 have already been explained, and are used to detect the power-on determining voltage by monitoring the power-on reset signal PON included in a plurality of semiconductor devices formed on a wafer W. The storage unit 430 stores therein the detected power-on determining voltage in association with the position of the semiconductor device 10 on the wafer W. This clearly shows a relationship of the position of the semiconductor device 10 on the wafer W with the power-on determining voltage, making it possible to understand processing conditions based thereon. The processing conditions obtained can be used for feedback to the following lots, thereby improving yields.

It is not necessary to store the power-on determining voltages themselves in the storage unit 430, but information relating to the power-on determining voltages, such as information indicating whether a detected power-on determining voltage is higher or lower than the design value, can be stored instead.

It is apparent that the present invention is not limited to the above embodiments, but may be modified and changed without departing from the scope and spirit of the invention.

What is claimed is:

1. A device comprising:
an internal circuit that receives a power-supply voltage;
a power-on determining circuit that supplies a power-on reset signal to the internal circuit in response to the power supply voltage and activates the power-on reset signal, when a level of the power-supply voltage is lower than a level of a power-on determining voltage, so that the internal circuit performs a predetermined reset operation, and deactivates the power-on reset signal when the level of the power-supply voltage is higher than the level of the power-on determining voltage; and
a detection-voltage producing circuit that adjusts the level of the power-on determining voltage.

2. The device as claimed in claim 1, wherein the detection-voltage producing circuit includes a fuse element and the level of the power-on determining voltage may be changed by trimming the fuse element.

3. The device as claimed in claim 1, further comprising a monitor pad coupled to an output node of the power-on determining circuit and serving as carrying out a an output of the power-on reset signal to an apparatus to be provided outside of the device.

4. A device comprising:
first and second power supply lines;
an internal circuit coupled between the first and second power supply lines;
a detection-voltage producing circuit that is connected between the first and second power supply lines to produce a detection voltage, a level of the detection voltage being substantially proportional to a level of a power-supply voltage applied between the first and second power supply lines, the detection-voltage producing circuit that is capable of adjusting a proportional constant between the level of the power-supply voltage and the level of the detection voltage; and
a power-on determining circuit that supplies a power-on reset signal to the internal circuit in response to the power supply voltage, activates the power-on reset signal, when the level of the detection voltage is lower than a level of a predetermined power-on determining voltage, so that the internal circuit performs a predetermined reset operation, and deactivates the power-on reset signal when the level of the detection voltage is higher than the level of the predetermined power-on determining voltage.

5. The device as claimed in claim 4, wherein the power-on determining circuit includes:
a first transistor connected between the first and second power supply lines, the first transistor including a first control electrode that receives the detection voltage; and
wherein the level of the power-on determining voltage is produced in response to a threshold voltage of the first transistor.

6. The device as claimed in claim 5, further comprising a timing constant circuit coupled to the power-on determining circuit, and wherein the power-on determining circuit includes a second transistor connected in series to the first transistor between the first and second power supply lines, the second transistor includes a second control electrode, and the timing constant circuit supplies a control voltage to the second control electrode of the second transistor so that the second transistor is turned on after a certain period from which the device is supplied the power-supply voltage.

7. The device as claimed in claim 4, wherein the detection-voltage producing circuit includes a plurality of resistive elements connected in series between the first and second power supply lines and at least a fuse element that connected in parallel to one of the resistive elements.

8. The device as claimed in claim 7, wherein the resistive elements include at least one of a linear resistance, a diode element and a diode connected transistor.

9. The device as claimed in claim 4, further comprising a monitor pad coupled to an output node of the power-on determining circuit and serving as carrying out a an output of the power-on reset signal to an apparatus to be provided outside of the device.

10. A method of adjusting a level of a power-on determining voltage of a device, the device compressing an internal circuit, a power-on determining circuit and a detection-voltage producing circuit, the power-on determining circuit activating a power-on reset signal, when a level of a power-supply voltage is lower than a level of a power-on determining voltage, so that the internal circuit performs a predetermined reset operation, and deactivating the power-on reset signal when the level of the power-supply voltage is higher than the level of the power-on determining voltage, the method comprising:
detecting the level of the power-on determining voltage;
comparing the level of the power-on determining voltage with a level of a design power-on determining voltage; and
performing a fuse trimming, in which one or ones of a plurality of fuse element included in the detection-voltage producing circuit are trimmed so that the level of the power-on determining voltage is adjusted, based on a result of the comparing.
